(19) United States
(12) Patent Application Publication
(10) Pub. No.: US 2009/0302477 A1
(43) Pub. Date: Dec. 10, 2009

(54) Integrated circuit with embedded contacts

(76) Inventors: Yakov Shor, Beer Sheva (IL); Yuval Najari, Mefalsim (IL); Lior Gadot, Moshav Shahar (IL); Effi Aboody, Ness Ziona (IL); Semeon Altshuler, Rishon Le Zion (IL); Nuriel Amir, Moshav Arugot (IL)

Correspondence Address: INTEL CORPORATION;c/o CPA Global, P.O. BOX 52050, MINNEAPOLIS, MN, 55402, US

(21) Appl. No.: 12/156,999

(22) Filed: Jun. 6, 2008

(51) Int. Cl. H01L 23/522; H01L 21/768

(52) U.S. Cl. 257/773; 438/675; 257/E23.145; 257/E21.585

(57) ABSTRACT

In some embodiments, disclosed is an interconnect structure with embedded plugs.

### BACKGROUND

The present invention relates generally to contacts (or plugs) in an integrated circuit (IC) device and their connectivity to metal lines (or interconnect portions).

FIG. 1 shows a side view of a portion of an IC with a conventional plug and metal line structure. The depicted IC has a substrate 102 supporting contacts 110 (110A to 110B) and a dielectric layer 104. The contacts 112 are electrically coupled to circuit components (e.g., transistor or other circuit component contacts, etc.) built on the substrate but not shown for simplicity.

Typically, the dielectric 104 is formed atop the substrate and then contact cavities are etched out of it, atop the contacts 110, to receive a suitable conductive material such as tungsten or copper (e.g., through chemical vapor deposition or plating) to form plugs 112. The resulting surface above the dielectric and plugs is typically then polished, and an etch stop layer (115) may then be deposited atop the now planer dielectric 104/plug 112 surface. From here, another dielectric layer 108 (which usually has an etch rate different from the etch stop layer 115) and a photo resist layer (not shown) atop the dielectric layer 108 are deposited so that a metal line (or layer) trench can be lithographically formed and etched out of the dielectric 108 to form a metal layer 114, which connects to the plugs 112. (ICs typically have one or more metal lines such as so-called M1, M2, etc. lines making up part of an interconnect structure to connect different circuit nodes to each other, as well as to signals or power connections external to the IC.)

Unfortunately, with such a process, some of the plugs may be recessed, such as is shown with plug 112C, and thereby not make adequate electrical contact with the metal line 114. Other problems may also exist with this and similar conventional IC interconnect processes and structures. Accordingly, new approaches may be desired.

### BRIEF DESCRIPTION OF THE DRAWINGS

Embodiments of the invention are illustrated by way of example, and not by way of limitation, in the figures of the accompanying drawings in which like reference numerals refer to similar elements.

FIG. 1 is a side view of a portion of a conventional integrated circuit showing plugs connected to a metal line.

FIG. 2 is a side view of a microscopic image showing plugs embedded in a metal line in accordance with some embodiments.

FIGS. 3A-3D show progressive stages of plug and metal line formation in an integrated circuit interconnect structure in accordance with some embodiments.

FIGS. 4A-4E show progressive stages of plug and metal line formation in an integrated circuit interconnect structure in accordance with other embodiments.

FIGS. 5A-5D show progressive stages of plug and metal line formation in an integrated circuit interconnect structure in accordance with still other embodiments.

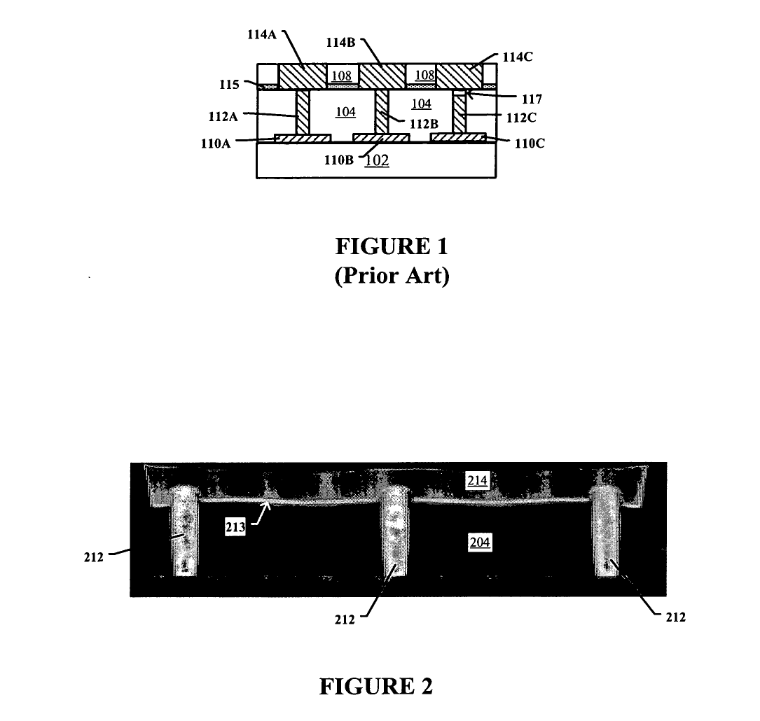

### DETAILED DESCRIPTION

FIG. 2 is a a microscopic image showing a side view of a cross-sectional portion of an interconnect structure in an IC. Shown are plugs 212 in a dielectric 204 with a coupling layer 213 (e.g., barrier layer) sandwiched between the plug/dielectric surface and an upper metal line (or line portions) 214. With this approach, the plug is embedded in the upper metal, i.e., the upper parts of the plugs 212 are embedded into the underside of the metal line 214. This can provide better electrical contact, as well as greater process margins for enabling the interconnect structure to have satisfactory connectivity.

With conventional structures, the plug does not protrude into the upper metal. Thus, the contact surface is limited by the quality of the top surfaces of the plugs, which can make it difficult for consistent, suitable connections. On the other hand, with plugs embedded into interconnects, the contact-metal interface area is greater, e.g., due to additional contact with side surfaces. In addition, processes used to make the embedded plugs may be more reliable for providing consistent adequate interconnectivity between the plugs and their corresponding metal connections. Even if some of the plugs are recessed, it will be more likely that at least part of their upper parts will make contact with their associated upper metal line (interconnect) portions.

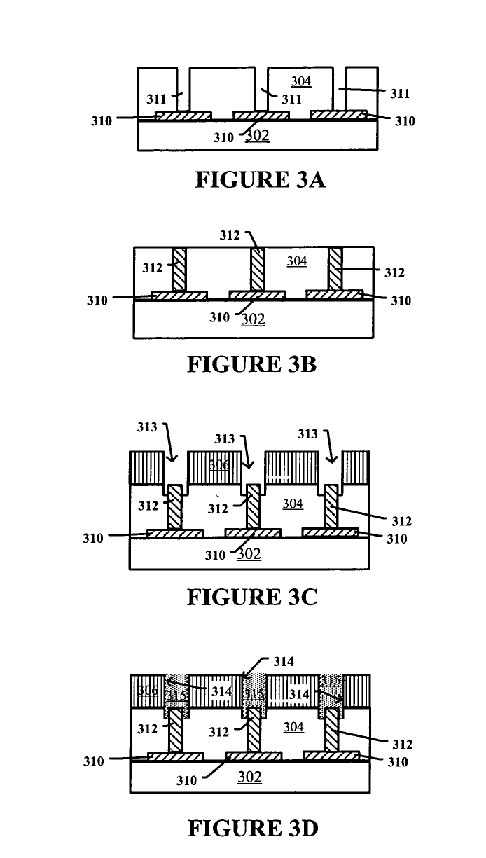

With reference to FIGS. 3A to 3D, a process for forming embedded plugs in accordance with some embodiments is discussed. (It should be understood that the exemplary processes discussed in the following sections may include more or less steps or may be performed in the context of a larger processing scheme.)

With particular reference to FIG. 3A, a dielectric layer 304 (e.g., a first dielectric layer) has been deposited over conductors 310 formed on a substrate 302. Conductors 310 suitably comprise a layer or layers of metal or metallic compounds as metal silicide or metal nitride or metal boride (e.g., cobalt silicide, titanium silicide, tungsten silicide, etc.), polycrystalline silicon (“polysilicon”), or a variety of other conductive materials. Alternatively, conductors 310 may be a diffused region (for example, an n+ junction or implant region), to which contact is to be made. They also could be formed from an ohmic contact material, such as cobalt Silicide, to inhibit Schottky coupling.

Substrate 302 consists of any suitable substrate material upon which or within which semiconductor devices may be formed. Suitable materials for substrate 302 include, for example, group IV semiconductors (e.g., Si, Ge, and SiGe), group III-V semiconductors (i.e., GaAs, InAs, and AlGaAs), and other less-conventional materials, such as diamond, and sapphire. Substrate 302 may comprise single crystal material, or may comprise one or more polycrystalline or amorphous epitaxial layers formed on a suitable base material. It will be appreciated that substrate 302 may also comprise various devices incorporated into a semiconductor material as well as interconnect structures comprising conductive paths and various dielectrics for isolating these conductive paths.

Dielectric 304 comprises a layer or layers of any suitable material such as silicon dioxide (doped or undoped), silicon nitride, silicon oxynitride, or low-k materials such as polyamide, poly(arylethers), parylene, polytetrafluroethylene, silsesquioxane, porous silicon dioxide, etc., or a variety of other substantially non-conductive materials. In the illustrated exemplary embodiment, dielectric 304 comprises a layer of silicon dioxide formed, e.g., using a chemical vapor deposition (CVD) process. As is known in the art, CVD processes can be used to deposit stable oxide layers through thermal decomposition and reaction of gaseous compounds, for example, through oxidation of silane. Alternatively, depending upon choice of materials, dielectric 304 may be formed utilizing low pressure chemical vapor deposition (LPCVD) or plasma enhanced chemical vapor deposition (PECVD) or high density plasma (HDP) CVD. The thickness of dielectric 304 may vary in accordance with the targeted feature size.

The dielectric layer 304 is patterned in order to form plug cavities 311 extending to and exposing a portion of contacts 310. Patterning may suitably be performed using various known lithographic techniques, for example, conventional optical lithography (including, for example, I-line and deep-UV), X-ray, or E-beam lithography. In an exemplary embodiment, an optical lithography process followed by a plasma-etching process may be used to pattern plug cavities 311 in dielectric layer 304.

The plug cavities 311 are filled (or partially filled) with conductive material to form plugs 312 as shown in FIG. 3B. The conductive plugs 312 may be formed from a single material or a combination of materials. Suitable materials include, for example, titanium, TiN, tantalum, TaN, tungsten, WN, molybdenum, polysilicon, silicide, aluminum, aluminum alloy, copper, and the like. Plugs 312 may be fabricated using a variety of conventional techniques. In an exemplary embodiment, plugs 312 may be formed through PVD (physical vapor deposition) or CVD deposition of one or more of the conductive materials used to make them with or without thermal annealing for low resistance conductive phase formation.

From here, an additional (e.g., second) dielectric layer (306 in FIGS. 3C and 3D) is deposited atop the surface defined by dielectric 304 and the tops of plugs 312. Any suitable material may be used for this additional dielectric, although it should have suitably different etch rates from the first dielectric 304 and plugs 312, as discussed below, to etch metal line (interconnect) trenches with a sufficient amount of the upper portions of the plugs, including their upper sidewalls, so that they can be embedded into appropriate metal line portions. For example, if the lower dielectric 304 is formed from silicon dioxide, suitable second dielectric materials could include various inorganic materials such as silicon nitride, silicon oxynitride, and the like.

In some exemplary embodiments, second dielectric layer 306 comprises a layer of silicon nitride deposited, for example, using a plasma enhanced CVD (PECVD) nitride deposition process. A photo-resist layer may be formed atop it, and the dielectric layer 306 can then be patterned to form trenches 313 (FIG. 3C). In an exemplary embodiment, conventional photo-resist and plasma-etch processes may be used to pattern the additional dielectric layer 306. That is, a mask layer (e.g., photo-resist) may be applied to the top of additional layer 306 then exposed and removed in accordance with the desired interconnect (e.g., metal line) wiring pattern.

Metal line (interconnect) trench 313 is then formed using a suitable etch process. Specifically, an etch process is chosen such that second dielectric layer 306 has an etch rate greater than first dielectric layer 304, which has an etch rate greater than plug 312 for the implemented etch process. Those skilled in the art will recognize that plasma etch variables such as gas composition, pressure, RF energy, and the like, may be optimized in accordance with material choices.

As can be seen, the trenches 313 are formed so that upper side surfaces of the plugs 312, as well as their tops, become exposed. This can occur with an etch process that etches away the lower dielectric 304 faster than the plugs. Any suitable method can be used to determine how long the etch process should occur until trenches 313 are suitably formed. For example, in some embodiments, once plug material (e.g., tungsten) is sensed by instruments used to perform etching, the etching could continue for a predefined amount of time thereafter (e.g., 2-3 seconds)or alternatively, until some measured condition (dielectric depth once plug detected) is satisfied.

From here, the exposed dielectric and plug material may be chemically etched or cleaned, e.g., using an ethylene glycol process and the metal for creation the metal line may be applied. Alternatively, a coupling layer 314 such as tantalum nitride followed by the interconnect metal (metal line) 315 may be deposited. Either way, metal line 315 makes electrical contact with and embeds conductive plugs 312.

Interconnect (metal line) metal may consist of a layer or layers of various conductive materials, including, for example, titanium, titanium nitride, tantalum, tantalum nitride, tungsten nitride, aluminum, aluminum-copper alloys, gold, copper, silver, tungsten, or any other suitable conductive material. Depending on the choice of materials for metal 315 (e.g., in the case of copper or copper alloys), it may be advantageous to use one or more coupling layers 314, e.g., an adhesion layer, a wetting layer, a barrier layer, and/or a seed layer, between metal 315 and the dielectric and upper plug surfaces to be embedded prior to bulk metal deposition. As is known in the art, adhesion layers generally assist in strengthening the bond between metal and dielectric layers, and barrier layers provide a barrier to prevent the migration or alloying of one material into another (for example, copper diffusion into silicon dioxide). Wetting layers promote metal-fill in high aspect ratio features. In this regard, it should be appreciated that a single material may exhibit one or more of these properties in a particular context.

Deposition of interconnect metal 315 may be performed using conventional techniques. For example, a layer of aluminum could be deposited using either a single PVD process, a single CVD process, or a combination of PVD and CVD processes. Alternatively, metal line 315 could comprise copper deposited using electrochemical deposition (or “electroplating”). Copper may be desirable in that its conductivity is relatively high and it is less susceptible to electro-migration failure than many metals (for example, aluminum).

After the metal interconnect (line) layer has been applied, excess interconnect metal 315 and any coupling layers (if used) may be removed, e.g., via a chemical mechanical polishing (CMP) process thereby forming a substantially planar surface with inlaid metal wiring 315, as shown in FIG. 3D.

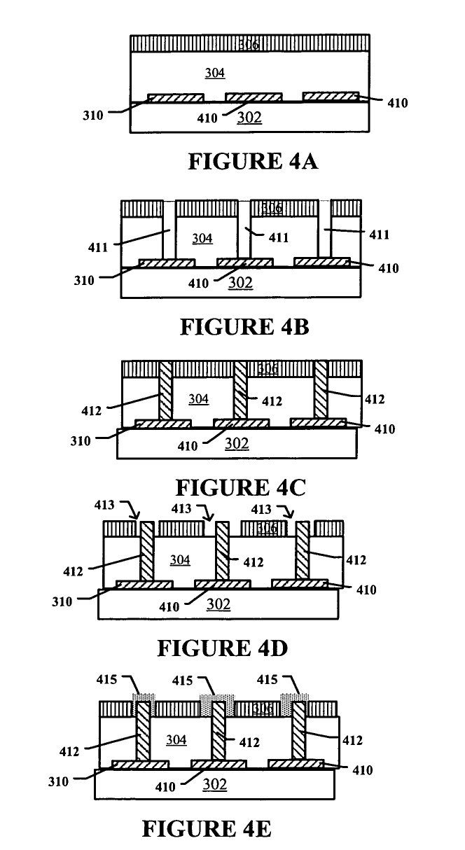

With reference to FIGS. 4A to 4E, another embodiment for making embedded interconnections is shown. With this embodiment, as shown in FIG. 4A, second dielectric layer 306 is formed before the plug cavities are patterned into the first dielectric 304. In some embodiments, the first dielectric may be formed from silicon oxide, while the second dielectric may be formed with silicon nitride, implemented as a hard mask.

Next, as shown in FIG. 4B, plug cavities 411 are formed, e.g., using masking and etching techniques discussed herein. From here, plug material (e.g., tungsten) may be deposited into the cavities to form plugs 412. The surface can then be polished, e.g., using a CMP methodology, resulting in a substantially planar upper dielectric/plug surface (FIG. 4C).

Next, the metal line trenches 413 may be formed, e.g., using a hard mask etch process, to remove the second dielectric 306 at a considerably faster rate than the plug material. Next, (FIG. 4E), the metal line material (e.g., copper) can be deposited, e.g., via bulk deposition, and the surface can then be polished.

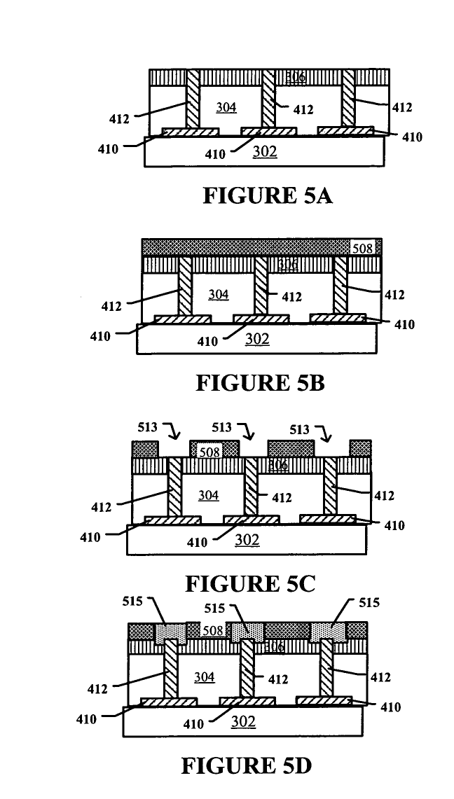

With reference to FIGS. 5A to 5D, another embodiment is shown. Starting with the device of FIG. 4C (5A), a third dielectric layer 506 is deposited atop second dielectric 306 (FIG. 5B), which in this embodiment, is implemented as a hard mask.

Next (FIG. 5C), metal line portion trenches 513 are patterned and etched out of the third dielectric layer 506, with the second layer (hard mask) 306 serving as an etch stop layer. From here, the hard mask (306) may further be etched (e.g., using a different, suitable etch process) to expose the upper side surfaces of the plugs. Finally, with or without a coupling layer, interconnect layer 515 is deposited (FIG. 5D), and the surface may then be polished using, e.g., a suitable CMP process.

In the preceding description, numerous specific details have been set forth. However, it is understood that embodiments of the invention may be practiced without these specific details. In other instances, well-known circuits, structures and techniques may have not been shown in detail in order not to obscure an understanding of the description. With this in mind, references to “one embodiment”, “an embodiment”, “example embodiment”, “various embodiments”, etc., indicate that the embodiment(s) of the invention so described may include particular features, structures, or characteristics, but not every embodiment necessarily includes the particular features, structures, or characteristics. Further, some embodiments may have some, all, or none of the features described for other embodiments.

In the preceding description and following claims, the following terms should be construed as follows: The terms “coupled” and “connected,” along with their derivatives, may be used. It should be understood that these terms are not intended as synonyms for each other. Rather, in particular embodiments, “connected” is used to indicate that two or more elements are in direct physical or electrical contact with each other. “Coupled” is used to indicate that two or more elements co-operate or interact with each other, but they may or may not be in direct physical or electrical contact.

The invention is not limited to the embodiments described, but can be practiced with modification and alteration within the spirit and scope of the appended claims. For example, it should be appreciated that the present invention is applicable for use with all types of semiconductor integrated circuit (“IC”) chips. Examples of these IC chips include but are not limited to processors, controllers, chip set components, programmable logic arrays (PLA), memory chips, network chips, and the like.

It should be appreciated that example sizes/models/values/ranges may have been given, although the present invention is not limited to the same. As manufacturing techniques (e.g., photolithography) mature over time, it is expected that devices of smaller size could be manufactured. In addition, well known power/ground connections to IC chips and other components may or may not be shown within the FIGS, for simplicity of illustration and discussion, and so as not to obscure the invention. Further, arrangements may be shown in block diagram form in order to avoid obscuring the invention, and also in view of the fact that specifics with respect to implementation of such block diagram arrangements are highly dependent upon the platform within which the present invention is to be implemented, i.e., such specifics should be well within purview of one skilled in the art. Where specific details (e.g., circuits) are set forth in order to describe example embodiments of the invention, it should be apparent to one skilled in the art that the invention can be practiced without, or with variation of, these specific details. The description is thus to be regarded as illustrative instead of limiting.

What is claimed is:

1. A device, comprising:
an integrated circuit having an interconnect line; and
a plug with a plug end embedded into a portion of said line to electrically couple the line portion to one or more circuit elements.

2. The device of claim 1, in which at least one coupling layer is sandwiched between the plug end and the line portion.

3. The device of claim 2, in which the at least one coupling layer comprises a barrier layer.

4. The device of claim 1, in which the line portion embedding the plug end is disposed within first and second dielectric layers.

5. The device of claim 4, in which the first and second dielectric layers are adjacent to one another without an etch stop layer interposed between them.

6. The device of claim 5, in which the second dielectric layer constitutes a hard mask.

7. The device of claim 1, in which the plug end includes a top surface and one or more upper side surfaces.

8. A method, comprising:
providing a first dielectric layer having one or more plugs;
depositing onto the first dielectric layer a second dielectric layer; and
etching an interconnect trench into the first and second dielectric layers for at least some of the one or more plugs, wherein upper ends of the at least some of the one or more plugs are exposed for coupling to an interconnect.

9. The method of claim 8, in which a separate trench is etched for each of the at least some of the one or more plugs.

10. The method of claim 8, comprising depositing interconnect metal into the interconnect trenches to embed the exposed upper ends of the at least some of the one or more plugs, the interconnect metal being different from that used for the one or more plugs.

11. The method of claim 11, further comprising depositing a coupling layer into the interconnect trenches and then depositing the interconnect metal over the coupling layer to embed the exposed upper ends of the at least some of the one or more plugs.

12. The method of claim 11, in which the coupling layer is a seed layer.

13. The method of claim 8, in which the second dielectric layer is implemented as a hard mask.

14. An integrated circuit device having one or more plugs embedded into one or more interconnects in accordance with the method of claim 8.

15. A method, comprising:
providing a first dielectric layer;
depositing onto the first dielectric layer a second dielectric layer;
etching one or more plug cavities into the second and first dielectric layers;
depositing plug material into the one or more plug cavities to form one or more plugs; and
etching out of at least the second dielectric layer an interconnect trench for each plug to expose its top surface and at least part of its upper side surface so that it can be embedded into an interconnect.

16. The method of claim 15, wherein the second dielectric is implemented as a hard mask.

17. The method of claim 16, comprising a third dielectric layer onto the second dielectric layer.

18. The method of claim 17, in which the interconnect trenches are etched out of the third and second dielectric layer.
